(19) United States
(12) Patent Application Publication
(10) Pub. No.: US 2006/0094181 A1
(43) Pub. Date: May 4, 2006

(54) METHOD FOR FABRICATING SEMICONDUCTOR DEVICE HAVING A TRENCH STRUCTURE

(75) Inventors: Jae-Seon Yu, Ichon-shi (KR); Phil-Goo Kong, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR, INC.

(21) Appl. No.: 11/149,173

(22) Filed: Jun. 10, 2005

(30) Foreign Application Priority Data
Oct. 30, 2004 (KR) 10-2004-0087700

(51) Int. Cl. H01L 21/8238; H01L 21/302

(52) U.S. Cl. 438/199; 438/713

(57) ABSTRACT

Disclosed is a method for fabricating a semiconductor device capable of preventing a residue from being generated during etching a gate conductive layer and forming a plurality of trenches having an identical width in a substrate. The method includes: selectively etching a substrate by employing tetramethylammoniumhydroxide (TMAH) solution, thereby forming a plurality of trenches of which lateral slopes are gradual; and forming a plurality of gate patterns on the substrate such that each sloped portion of the trenches becomes a part of a channel of the individual gate pattern.

### FIELD OF THE INVENTION

The present invention relates to a method for fabricating a semiconductor device; and more particularly, to a method for fabricating a semiconductor device capable of preventing a residue from being generated during etching a gate conductive layer and forming a plurality of trenches having an identical width in a substrate.

### DESCRIPTION OF RELATED ARTS

As a scale of integration of a semiconductor device has increased, a channel length of a transistor has been decreased. If the channel length gets shorter, a short channel effect that a threshold voltage abruptly decreases arises more frequently.

Accordingly, in order to increase the channel length of a gate, a plurality of trenches are formed in a substrate and a gate pattern is formed on the trenches.

FIGS. 1A and 1B are cross-sectional views illustrating a method for fabricating a conventional semiconductor device.

Referring to FIG. 1A, a substrate 10 provided with a field oxide layer 11 is selectively subject to a dry etch, thereby forming a plurality of trenches T. At this time, each lateral side of the trenches has a vertical profile.

Subsequently, as shown in FIG. 1B, a gate oxide layer 12, a conductive layer 13 and an insulation layer 14 for a hard mask are sequentially deposited on the substrate 10. Afterwards, the gate oxide layer 12, the conductive layer 13 and the insulation layer 14 for the hard mask are patterned, thereby forming a plurality of gate patterns G1 on an upper portion of the substrate 10 such that the lateral sides of the trenches T become a portion of each gate pattern G1.

During depositing the conductive layer 13, the conductive layer 13 is deposited with a different thickness in a boundary of portions where the substrate is etched and the substrate is not etched due to height differences between the lateral sides of the trenches 12. Accordingly, after the conductive layer 13 is etched for forming the gate patterns G1, a residue R of the conductive layer 13 remains in the trench region of the boundary of the portions where the substrate is etched and the substrate is not etched. This residue R induces an electric short between interconnection lines of the gate patterns G1.

Furthermore, in order to secure an operation reliability of the semiconductor device, it is required to have a uniform etch selectivity according to a location of the substrate to form a uniform channel length of the gate pattern. In case of performing the dry etch to the substrate without an additional etch stop layer, there may be a problem that a width of the individual trench T gets different since an etched amount of the substrate is different due to the etch selectivity that varies depending on the location of the substrate

### SUMMARY OF THE INVENTION

It is, therefore, an object of the present invention to provide a method for fabricating a semiconductor device capable of preventing a residue from being generated during etching a gate conductive layer and forming a plurality of trenches having an identical width in a substrate.

In accordance with one aspect of the present invention, there is provided a method for fabricating a semiconductor device, including the steps of: selectively etching a substrate by employing tetramethylammoniumhydroxide (TMAH) solution, thereby forming a plurality of trenches of which lateral slopes are gradual; and forming a plurality of gate patterns on the substrate such that each sloped portion of the trenches becomes a part of a channel of the individual gate pattern.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A and 1B are cross-sectional views illustrating a method for fabricating a conventional semiconductor device; and

FIGS. 2A to 2F are cross-sectional views illustrating a method for fabricating a semiconductor device in accordance with a preferred embodiment of the present invention.

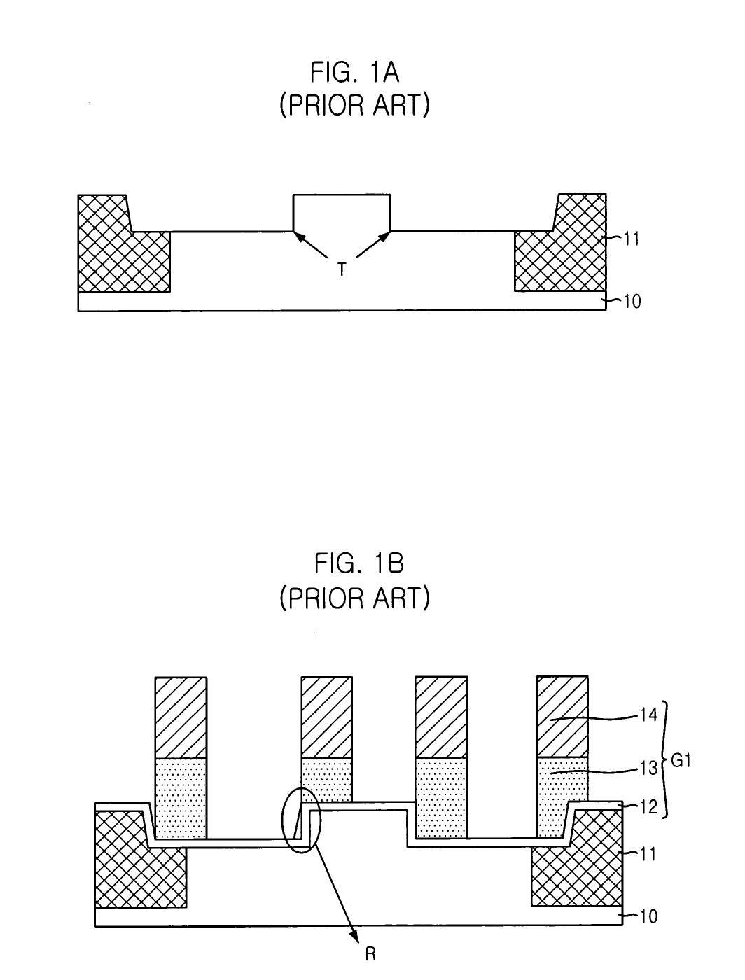

### DETAILED DESCRIPTION OF THE INVENTION

Hereinafter, detailed descriptions on preferred embodiments of the present invention will be provided with reference to the accompanying drawings.

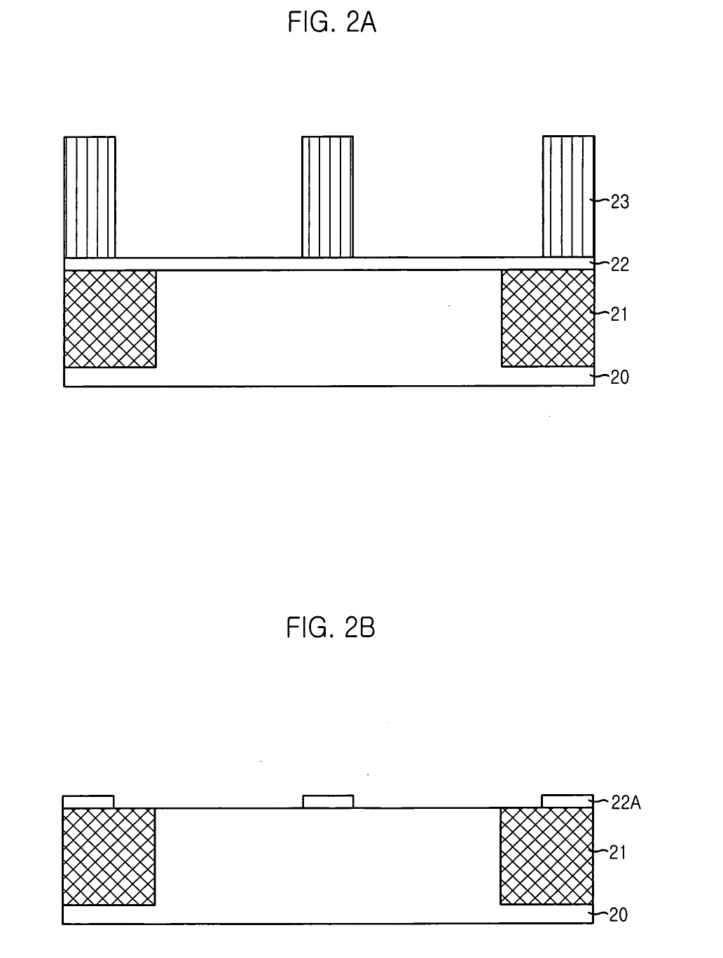

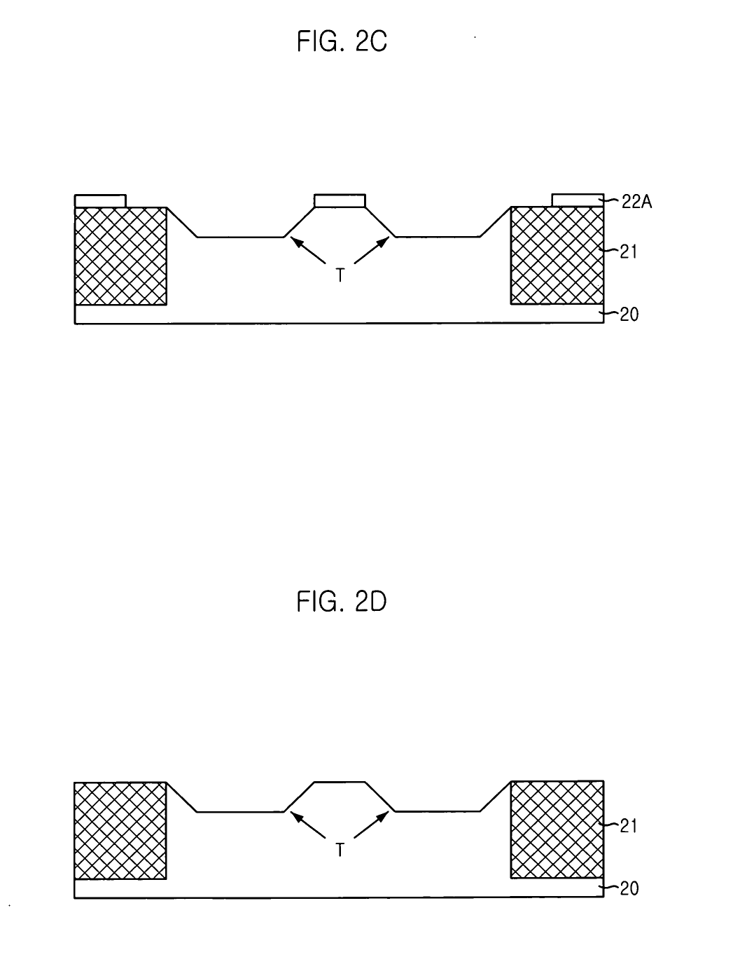

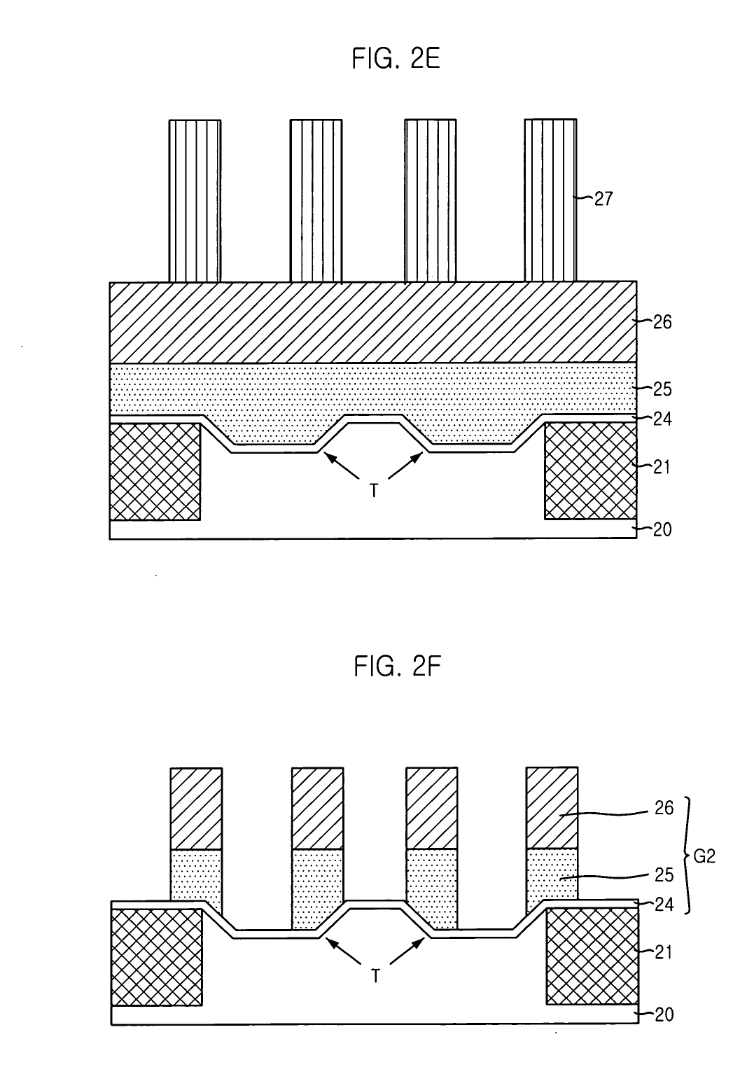

FIGS. 2A to 2F are cross-sectional views illustrating a method for fabricating a semiconductor device in accordance with a preferred embodiment of the present invention.

Referring to FIG. 2A, a field oxide layer 21 for a device isolation is formed on a substrate 20.

Subsequently, a sacrificial layer 22 for use in a hard mask is formed on the substrate 20. The sacrificial layer 20 includes an oxide layer, e.g., an aluminum oxide layer, a nitride layer or a tungsten layer.

Next, a first photoresist pattern 23 for forming a plurality of trenches T is formed on the sacrificial layer 22.

As shown in FIG. 2B, the sacrificial layer 22 is selectively etched by using the first photoresist pattern 23 as an etch mask, thereby forming a mask pattern 22A.

Next, as shown in FIG. 2C, a wet etch employing tetramethylammoniumhydroxide (TMAH) solution is performed with use of the mask pattern 22A as an etch mask. Thus, a plurality of trenches T with a gradual slope are formed in the substrate 20.

At this time, a temperature of the TMAH solution ranges from approximately 50° C. to approximately 100° C. and thus, the TMAH solution has a high selectivity with respect to the mask pattern 22A and the field oxide layer 21. Accordingly, the mask pattern 22A and bottom portions of the field oxide layer 21 are not etched. Thus, a line width of an individual etch pattern, i.e., the individual trench T, is uniformly maintained and an etched amount is uniform with regardless of a location of the substrate 20.

Herein, before or after the wet etch for forming the plurality of trenches T is performed, one more step of performing a dry etch to a portion where the plurality of trenches T are formed in the substrate 20 by using a gas selected from a group consisting of oxygen (O₂), argon (Ar), CₓFₓ, NₓFₓ and chlorine (Cl₂) can be included in order to control the slope of the individual etch pattern.

Subsequently, as shown in FIG. 2D, the mask pattern 22A formed on the substrate 20 is removed. In case of forming the mask pattern 22A with use of an oxide layer, the mask pattern 22A is removed through a wet etch employing buffered oxide etchant (BOE) solution or hydrogen fluoride (HF) solution, or a dry etch employing a gas selected from a group consisting of CₓFₓ, NFₓ SFₓ.

In case of forming the mask pattern 22A with use of a nitride layer, the mask pattern 22A is removed through a wet etch employing phosphate (H₂PO₄) solution maintained at a temperature ranging from approximately 150° C. to approximately 200° C. or a dry etch employing a gas selected from a group consisting of CₓFₓ, NFₓ and SFₓ.

In case of forming the mask pattern 22A with use of a tungsten layer, the mask pattern 22A is removed through a wet etch employing a standard clean (SC)-1 solution, i.e., a solution obtained by mixing ammonium hydroxide (NH₄OH), hydrogen peroxide (H₂O₂) and deonized water (H₂O), maintained at a temperature ranging form approximately 50° C. to approximately 80° C. or a dry etch employing a gas selected from a group consisting of Cl₂, boron trichloride (BCl₃), CₓFₓ, NFₓ and SFₓ.

Subsequently, as shown in FIG. 2E, a gate oxide layer 24, a conductive layer 25 and an insulation layer 26 for use in a hard mask are sequentially formed on the substrate 20. The conductive layer 25 is formed by using a material selected from a group consisting of WSiₓ, W, CoₓSiₓ, TiₓSiₓ and a family of polysilicon. Also, the conductive layer 27 can be formed in a stack structure by stacking at least two materials among the aforementioned materials.

Subsequently, a second photoresist pattern 27 is formed on the insulation layer 26.

Next, as shown in FIG. 2F, the insulation layer 26 is selectively etched by using the second photoresist pattern 27 as an etch mask and afterwards, the second photoresist pattern 27 is removed. Subsequently, the conductive layer 25 is etched by using the etched insulation layer 26 as the etch mask, thereby forming a plurality of gate patterns G2. Despite the fact that the gate patterns G2 are not properly arranged in the etched substrate 20, it is still possible to prevent a residue from remaining on the conductive layer 25 in an etched region during etching the conductive layer 25 since the gate patterns G2 are formed on the substrate 20 with a gradual slope.

In case of forming the conductive layer 25 in a stack structure by stacking a top layer including at least more than one of WSix, W, CoₓSiₓ and TiₓSiₓ, and a bottom layer based on polysilicon, the top layer is etched through using a high density plasma etch apparatus such as an inductively coupled plasma (ICP) type etch apparatus, a decoupled plasma source (DPS) type etch apparatus and an electron cyclotron resonance (ECR) type etch apparatus. Particularly, the top layer is etched by using at least one gas selected from a group consisting of BCl₃, CₓFₓ, NFₓ and SFₓ with an amount ranging from approximately 10 sccm to approximately 50 sccm, a Cl₂ gas with an amount ranging from approximately 50 sccm to approximately 200 sccm or a mixed gas thereof.

Herein, in case of employing the ICP type etch apparatus or the DPS type etch apparatus, the etching process is performed by using a source power ranging from approximately 500 W to approximately 2,000 W and adding more than one gas selected from a group consisting of O₂ gas with an amount ranging from approximately 1 sccm to approximately 20 sccm, nitrogen (N₂) gas with an amount ranging from approximately 1 sccm to approximately 100 sccm, Ar gas with an amount ranging from approximately 50 sccm to approximately 200 sccm and helium (He) ranging from approximately 5 sccm to approximately 200 sccm in order to obtain the vertical etch profile.

In case of using the ECR type apparatus, the etching process is performed by using a microwave power ranging from approximately 1,000 W to approximately 3,000 W and adding more than one selected from a group consisting of O₂ gas with an amount ranging from approximately 1 sccm to approximately 20 sccm, N₂ gas with an amount ranging from approximately 1 sccm to approximately 100 sccm, Ar gas with an amount ranging from approximately 50 sccm to approximately 200 sccm and He with an amount ranging from approximately 5 sccm to approximately 200 sccm in order to obtain the vertical etch profile.

The bottom layer is etched without causing any loss of the top layer and the gate oxide layer 24 by using a plasma to which hydrogen bromide (HBr) and O₂ gases are added at the high density plasma etch apparatus such as the ICP type etch apparatus, the DPS type etch apparatus and the ECR type etch apparatus.

Herein, in case of using the ICP type etch apparatus or the DPS etch apparatus, the etching process is performed by using a source power with an amount ranging from approximately 500 W to approximately 2,000 W and adding at least one gas selected from approximately 50 sccm to approximately 200 sccm of the HBr gas and approximately 2 sccm to approximately 20 sccm of the O₂ gas.

Furthermore, in case of the ECR type etch apparatus, the etching process is performed by using a microwave power ranging from approximately 1,000 W to approximately 3,000 W and a gas selected from approximately 50 sccm to approximately 200 sccm of the HBr gas and approximately 2 sccm to 20 sccm of the O₂ gas or a mixed gas thereof.

As described above, the plurality of trenches with the gradual slope are formed through performing the wet etch employing the TMAH solution on the substrate. Accordingly, it is possible to eliminate the residue generation during etching the conductive layer for forming the gate patterns since the thickness of the conductive layer decreases in proportion to a level of the decrease in the height of the lateral sides of the trenches. Furthermore, it is also possible to obtain the etched amount of the substrate uniform regardless of the location of the substrate.

In accordance with the present invention, the plurality of trenches with the gradual slop are formed through the wet etch employing the TMAH solution. Accordingly, the residue of the conductive layer is removed and the width of the individual trench becomes uniform throughout the substrate.

The present application contains subject matter related to the Korean patent application No. KR 2004-0087700, filed in the Korean Patent Office on Oct. 30, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. A method for fabricating a semiconductor device, comprising the steps of:
selectively etching a substrate by employing tetramethylammoniumhydroxide (TMAH) solution, thereby forming a plurality of trenches of which lateral slopes are gradual; and
forming a plurality of gate patterns on the substrate such that each sloped portion of the trenches becomes a part of a channel of the individual gate pattern.

2. The method of claim 1, further including the step of selectively performing a dry etch to the substrate where the plurality of trenches are supposed to be formed before the step of etching the substrate to form the plurality of trenches.

3. The method of claim 1, after the step of etching the substrate to form the plurality of trenches, further including the step of performing a dry etch to the substrate where the plurality of trenches are formed.

4. The method of claim 2, wherein the dry etch employs a gas selected from a group consisting of oxygen (O₂), argon (Ar), CₓFₓ, NₓFₓ and Chlorine (Cl₂).

5. The method of claim 3, wherein the dry etch employs a gas selected from a group consisting of oxygen (O₂), argon (Ar), CₓFₓ, NₓFₓ and Chlorine (Cl₂).

6. The method of claim 1, wherein the step of forming the plurality of trenches includes the steps of:
forming a mask pattern defining a plurality of trench regions;
performing a wet etch to the substrate by using the tetramethylammoniumhydroxide (TMAH) solution with use of the mask pattern as an etch mask; and
removing the mask pattern.

7. The method of claim 6, wherein the tetramethylammoniumhydroxide (TMAH) solution is maintained at a temperature ranging from approximately 50° C. to approximately 100° C. to make the trenches have a high etch selectivity with respect to the mask pattern.

8. The method of claim 6, wherein the mask pattern includes one of an oxide layer, a nitride layer and a tungsten layer.

9. The method of claim 8, wherein if the mask pattern is formed by using the oxide layer, the mask pattern is removed through one of a wet etch using a solution selected from buffered oxide etchant (BOE) and hydrogen fluoride (HF) and a dry etch using a gas selected from a group consisting of CₓFₓ, NFₓ, and SFₓ.

10. The method of claim 8, wherein if the mask pattern is formed by using the nitride layer, the mask pattern is removed though one of a wet etch employing a phosphate (H₂PO₄) solution maintained at a temperature ranging from approximately 150° C. to approximately 200° C. and a dry etch using a gas selected from a group consisting of CₓFₓ, NFₓ and SFₓ.

11. The method of claim 8, wherein if the mask pattern is formed by using the tungsten layer, the mask pattern is removed through one of a wet etch using a standard clean (SC)-1 solution obtained by mixing ammonium hydroxide (NH₄OH), hydrogen peroxide (H₂O₂) and deionized water (H₂O) and maintained at a temperature ranging from approximately 50° C. to approximately 80° C. and a dry etch using a gas selected from a group consisting of chlorine (Cl₂), boron trichloride (BCl₃), CₓFₓ, NFₓ and SFₓ.
